(19) United States
(12) Patent Application Publication
(10) Pub. No.: US 2025/0149493 A1
(43) Pub. Date: May 8, 2025

(54) INTEGRATED DEVICE PACKAGE WITH REDUCED THICKNESS

(71) Applicant: Skyworks Solutions, Inc., Irvine, CA (US)

(72) Inventors: Dae Keun Park, Irvine, CA (US); Ki Wook Lee, Irvine, CA (US); Alan Sangone Chen, Leesburg, FL (US); Takashi Inoue, Singapore (SG); Sundeep Nand Nangalia, Raleigh, NC (US)

(21) Appl. No.: 18/933,246

(22) Filed: Oct. 31, 2024

Related U.S. Application Data
(60) Provisional application No. 63/547,043, filed on Nov. 2, 2023.

(51) Int. Cl. H01L 23/00; H01L 23/31; H01Q 1/22

(52) U.S. Cl. CPC H01L 24/29; H01L 23/3107; H01L 24/16; H01L 24/32; H01L 24/73; H01Q 1/2283; H01L 2224/16227; H01L 2224/29011; H01L 2224/2919; H01L 2224/32225; H01L 2224/73203

(57) ABSTRACT

An integrated device package is disclosed. The integrated device package can include an integrated device die that is mounted to a carrier. The integrated device die has a bottom side facing the carrier and a top side opposite the bottom side. The integrated device package can include a cavity that is located between the bottom side of the integrated device die and the carrier, a cavity seal that at least partially seals the cavity, and a molding material that is disposed about the integrated device die. The integrated device die can be an acoustic wave filter.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/547,043, filed Nov. 2, 2023, titled “INTEGRATED DEVICE PACKAGE WITH REDUCED THICKNESS,” are hereby incorporated by reference under 37 CFR 1.57 in their entirety.

### BACKGROUND

### Technical Field

The field relates to device packages, and in particular, to integrated device packages with a reduced thickness having a cavity and a cavity seal.

### Description of Related Technology

An integrated device package can include an electrical component that is mounted on a carrier. The component can include an integrated device die (e.g., microelectronicmechanical systems (MEMS) die or an acoustic wave filter. Some components can include sensitive or moving parts that are preferred to be exposed to an air cavity. A surface acoustic wave (SAW) filter and a bulk acoustic wave (BAW) filter are examples of a sensitive component. Acoustic wave filters can be implemented in radio frequency electronic systems. For instance, filters in a radio frequency front end of a mobile phone can include acoustic wave filters.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to an integrated device package including: an integrated device die mounted to a carrier, the integrated device die having a bottom side facing the carrier and a top side opposite the bottom side; a cavity located between the bottom side of the integrated device die and the carrier; a cavity seal at least partially sealing the cavity; and a molding material disposed about the integrated device die.

In some embodiments, the techniques described herein relate to an integrated device package wherein the integrated device die is a surface acoustic wave filter.

In some embodiments, the techniques described herein relate to an integrated device package wherein the carrier is a printed circuit board.

In some embodiments, the techniques described herein relate to an integrated device package wherein the cavity is an air cavity.

In some embodiments, the techniques described herein relate to an integrated device package wherein the cavity seal includes an epoxy material.

In some embodiments, the techniques described herein relate to an integrated device package wherein the cavity seal and the molding material include different materials.

In some embodiments, the techniques described herein relate to an integrated device package wherein the cavity is free from the molding material.

In some embodiments, the techniques described herein relate to an integrated device package wherein the integrated device die is completely covered by the cavity seal.

In some embodiments, the techniques described herein relate to an integrated device package wherein the carrier includes a recess, and the integrated device die is at least partially positioned in the recess.

In some embodiments, the techniques described herein relate to an integrated device package further including an electronic component positioned between the bottom side of the integrated device die and the carrier, the electronic component electrically connected to the carrier.

In some embodiments, the techniques described herein relate to an integrated device package further including an electronic component positioned over the top side of the integrated device die, the electronic component electrically connected to the carrier.

In some embodiments, the techniques described herein relate to an integrated device package wherein the electronic component is electrically connected to the carrier through the integrated device die.

In some embodiments, the techniques described herein relate to an integrated device package wherein the integrated device die is at least partially positioned in a recess formed in the carrier.

In some aspects, the techniques described herein relate to an integrated device package including: an acoustic wave filter mounted to a carrier, the acoustic wave filter having a bottom side facing the carrier and a top side opposite the bottom side; a cavity located between the acoustic wave filter and the carrier, the bottom side of the acoustic wave filter exposed to the cavity; and a cavity seal at least partially sealing the cavity.

In some embodiments, the techniques described herein relate to an integrated device package further including a molding material overmolding the acoustic wave filter.

In some embodiments, the techniques described herein relate to an integrated device package wherein the carrier is a printed circuit board.

In some embodiments, the techniques described herein relate to an integrated device package wherein the cavity is an air cavity.

In some embodiments, the techniques described herein relate to an integrated device package wherein the cavity seal is a dielectric cavity seal.

In some aspects, the techniques described herein relate to a wireless communication device including: an integrated device package including an integrated device die mounted to a carrier, a cavity located between the integrated device die and the carrier, and a cavity seal at least partially sealing the cavity, the integrated device package is at least partially exposed to the cavity; and an antenna and a radio frequency front end electrically connected to the integrated device package.

In some embodiments, the techniques described herein relate to a wireless communication device wherein the integrated device package is an acoustic wave filter package and the cavity seal is a dielectric cavity seal.

### BRIEF DESCRIPTION OF THE DRAWINGS

Embodiments of this disclosure will now be described, by way of non-limiting example, with reference to the accompanying drawings.

FIG. 1 is a schematic cross-sectional side view of an integrated device package.

FIGS. 2-11B are schematic cross-sectional side views of integrated device packages according to embodiments.

FIG. 12 is a schematic diagram of a wireless communication device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Electronic components can be mounted on a carrier and packaged as an integrated device package. Certain electronic components such as filters (e.g., surface acoustic wave (SAW) filters and bulk acoustic wave (BAW) filters) can be pre-packaged, for example, at a wafer level, prior to being mounted to the carrier. For example, electronic components with a sensitive portion or a moving part can be pre-packaged to include a cap structure to define an air cavity. The cap structure can ensure that the sensitive portion or the moving part is isolated from a molding material when the electronic component is overmolded for packaging. However, such a cap structure adds a thickness to the electronic component and increases a thickness of the integrated device package.

Various embodiments disclosed herein relate to integrated device packages that omit the cap structure. An integrated device package according to some embodiments can include a carrier, an integrated device die (e.g., an acoustic wave filter) mounted to the carrier, a cavity seal at least partially sealing a cavity positioned between the carrier and the integrated device die, and a molding material over the integrated device die. The carrier can be a printed circuit board (PCB) and the integrated device die can be a filter that is flip-chip mounted to the carrier. In some embodiments, the carrier can include a recess, and at least a portion of the integrated device die can be positioned in the recess. The cavity seal can prevent or mitigate the molding material from entering the cavity positioned between the carrier and the integrated device die. In some embodiments, the cavity seal can completely seal the cavity. The integrated device package can include a second integrated device die positioned between the carrier and the integrated device die.

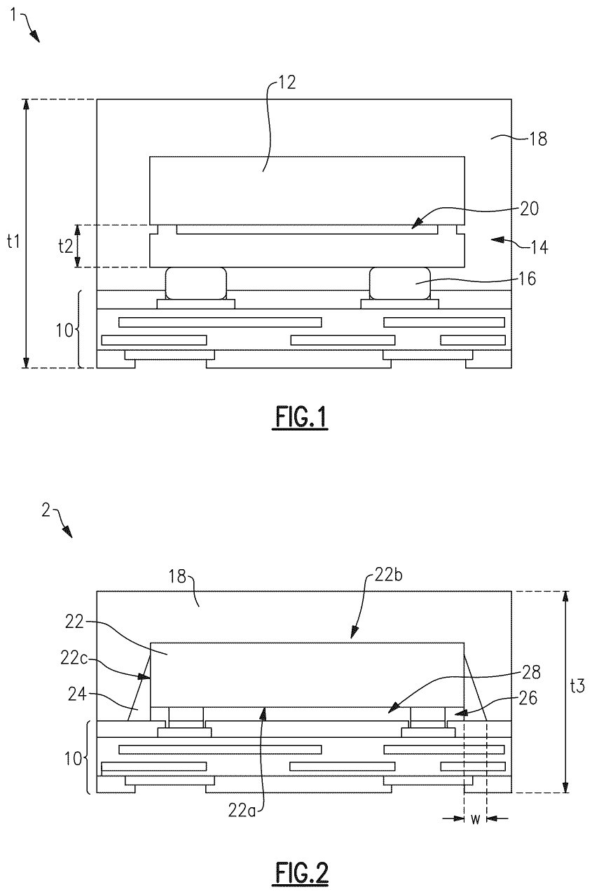

FIG. 1 is a schematic cross-sectional side view of an integrated device package 1. The integrated device package 1 includes a carrier 10, a pre-packaged filter 12 with a cap structure 14 bonded to the carrier 10 by way of solder balls 16, and a molding material 18 overmolding the pre-packaged filter 12. The cap structure 14 can provide a cavity 20 to ensure that a sensitive portion or a moving part of the pre-packaged filter 12 is isolated from the molding material 18 when the pre-packaged filter 12 is overmolded for packaging. The integrated device package 1 has a thickness t1 and the cap structure 14 has a thickness t2. Since the thickness h1 includes the thickness t2, the cap structure 14 increases the thickness t1 of the integrated device package 1 as compared to a similar structure without the cap structure 14. The thickness h2 can be in a range of, for example, 50 μm to 100 μm.

FIGS. 2-11B show various embodiments of integrated device packages that omit the cap structure 14. The integrated device packages of FIGS. 2-11B can have reduced thicknesses relative to the thickness h1 of the integrated device package 1 shown in FIG. 1.

FIG. 2 is a schematic cross-sectional side view of an integrated device package 2 according to an embodiment. The integrated device package 2 can include a carrier 10, a die (e.g., an integrated device die 22) mounted to the carrier 10, a cavity seal 24, and a molding material 18. The integrated device die 22 has a bottom side 22a, a top side 22b opposite the bottom side 22a, and a sidewall 22c that extends between the bottom side 22a and the top side 22b. The integrated device die 22 can be coupled to the carrier 10 by way of a connector 26. The integrated device package 2 can include a cavity 28 between the carrier 10 and the bottom side 22a of the integrated device die 22. In some embodiments, a height of the cavity 28 can depend at least in part on a height of the connector 26.

The carrier 10 can be any suitable carrier for receiving the integrated device die 22. For example, the carrier 10 can be a laminate substrate, such as a printed circuit board (PCB) or a leadframe. In some embodiments, the PCB can include a material such as an FR-1 material, an FR-4 material, a CEM-1 material, a CEM-3 material, or polyimide. In some embodiments, the integrated device package 2 can be coupled to an external device or a larger system through the carrier 10.

In some embodiments, the bottom side 22a of the integrated device die 22 can include a sensitive portion or a moving part that is exposed to the cavity 28. For example, the integrated device die 22 can be a filter (e.g., a surface acoustic wave (SAW) filter and a bulk acoustic wave (BAW) filter). Thus, the integrated device package 2 can be a filter package.

In some embodiments, the integrated device die 22 can be flip-chip mounted to the carrier 10. For example, the integrated device die 22 can be mounted to the carrier 10 by way of a land grid array (LGA) in which a plurality of pins are arranged in a grid pattern on a bottom side of the integrated device die 22 as the connector 26 and connected to pads on the carrier 10. For example, the integrated device die 22 can be mounted to the carrier 10 by way of a ball grid array (BGA) in which solder balls are used as the connector 26 to connect terminals on the bottom side of the integrated device die 22 to the pads on the carrier 10. For example, the integrated device die 22 can be mounted to the carrier 10 by way of a micro leadframe grid array (MGA) in which leads are arranged in a grid pattern around edges of the bottom side of the integrated device die 22 as the connector 26 and connected to pads on the carrier 10.

The molding material 18 can be disposed about (e.g., on, over, around, and/or near) the integrated device die 22. In some embodiments, the molding material 18 can completely overmold the integrated device die 22. In some embodiments, at least a portion of the carrier 10 below the integrated device die 22 can be free from the molding material 18. For example, a region between the integrated device die 22 and a corresponding portion of the carrier 10 can be completely free from the molding material 18. In other words, no portion of the molding material 18 may be positioned in the region between the integrated device die 22 and a corresponding portion of the carrier 10.

The cavity seal 24 can at least partially or completely seal the cavity 28. The cavity 28 can be an air cavity. In some embodiments, the cavity 28 can be filled with a gas (e.g., an inert gas). The cavity seal 24 can prevent or mitigate the molding material 18 from reaching the sensitive portion or the moving part of the integrated device die 22. Thus, the cavity 28 can be free from the molding material 18. The cavity seal 24 can be a dielectric cavity seal that includes a dielectric material. For example, the cavity seal 24 can include an epoxy material. The cavity seal 24 can have a material property (e.g., viscosity) that does not deform significantly when being applied around the cavity 28 such that the cavity seal 24 does not reach the sensitive portion or the moving part of the integrated device die 22. In some embodiments, the cavity seal 24 can be provided after mounting the integrated device die 22 to the carrier 10. The cavity seal 24 can be provided by any suitable method. For example, the cavity seal 24 can be provided by way of deposition, injection, or printing.

In some embodiments, the cavity seal 24 and the molding material 18 can include the same material but provided in a different manner. In some other embodiments, the cavity seal 24 and the molding material 18 can include different materials. For example, the cavity seal 24 may be more viscous than the molding material 18 at least when being provided.

In some embodiments, as shown in FIG. 2, the cavity seal 24 can at least partially be in physical contact with the sidewall 22c of the integrated device die 22 and the carrier 10. In some other embodiments, at least a portion of the cavity seal 24 can be disposed partially between the carrier 10 and the bottom side 22a of the integrated device die 22. For example, the portion of the cavity seal 24 can be positioned laterally between the connector 26 and the sidewall 22c of the integrated device die 22. A portion of the cavity seal 24 that is in physical contact with has a width w measured in a lateral direction. In some embodiments, the width w can be in a range of 1 μm to 150 μm or 10 μm to 100 μm.

The integrated device package 2 has a thickness t3. The thickness t3 of the integrated device package 2 is less than the thickness t1 of the integrated device package 1. For example, the thickness t3 can be thinner than the thickness t1 at least by the thickness t2 of the cap structure 14 shown in FIG. 1. In some applications, the thickness t3 can be 50 μm to 100 μm thinner than the thickness t1. Accordingly, the cavity seal 24 can enable the cap structure 14 of the integrated device package 1 to be omitted while proving the cavity 28 for the sensitive portion or the moving part of the integrated device die 22, such that the thickness t3 can be less than the thickness t1 without negatively affecting the integrity and/or the performance of the integrated device package 2.

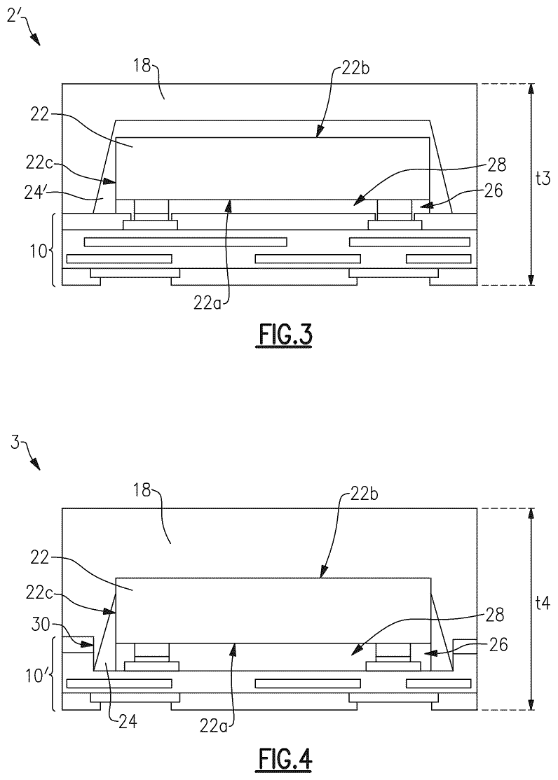

Any of the principles and advantages discussed herein can be combined in any suitable manner. FIGS. 3 to 11B show variations of the integrated device package 2 of FIG. 2. Unless otherwise noted, components of FIGS. 3 to 11B can be the same as or generally similar to like components of FIG. 2.

FIG. 3 is a schematic cross-sectional side view of an integrated device package 2′ according to an embodiment. The integrated device package 2′ can be generally similar to the integrated device package 2 of FIG. 2 except that a cavity seal 24′ of the integrated device package 2′ is disposed at least partially over the integrated device die 22. In some embodiments, the cavity seal 24′ can be disposed such that the entire top side 22b and the sidewall 22c are covered by the cavity seal 24′. Thus, in some embodiments, the integrated device die 22 can be completely covered by or embedded in the cavity seal 24′. The cavity seal 24′ can contribute to sealing the cavity 28 completely.

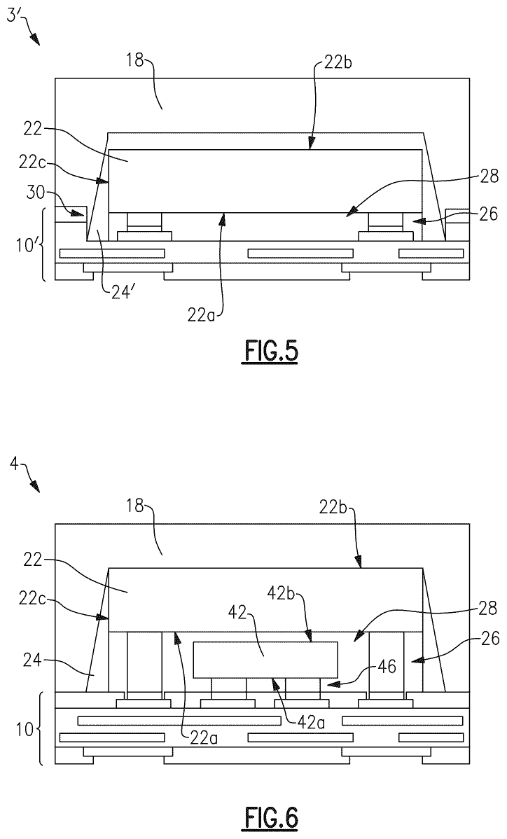

FIG. 4 is a schematic cross-sectional side view of an integrated device package 3 according to an embodiment. The integrated device package 3 can be generally similar to the integrated device package 2 of FIG. 2 except that a carrier 10′ of the integrated device package 3 has a recess 30 that is formed at least partially through a thickness of the carrier 10′. The integrated device die 22 can be at least partially positioned in the recess 30 of the carrier 10′. In some embodiments, the cavity seal 24 can be at least partially positioned in the recess 30 as shown in FIG. 4. In some other embodiments, the cavity seal 24 may seal a gap between the carrier 10′ and the sidewall 22c of the integrated device die 22 thereby sealing the cavity 28 without being positioned in the recess 30. The integrated device package 3 has a thickness t4. The thickness t4 of the integrated device package 3 can be less than the thickness t3 of the integrated device package 2. The difference between the thicknesses t3, t4 can be the depth of the recess 30, in some embodiments.

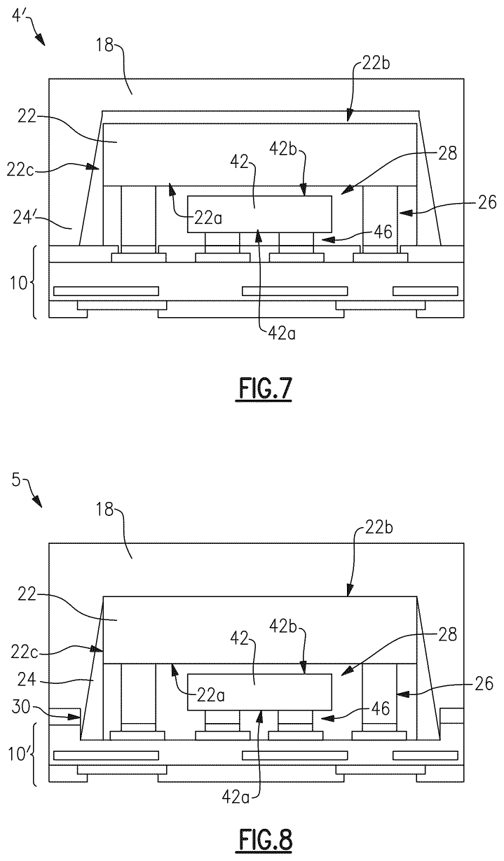

FIG. 5 is a schematic cross-sectional side view of an integrated device package 3′ according to an embodiment. The integrated device package 3′ can be generally similar to the integrated device package 3 of FIG. 4 but includes the cavity seal 24′ of FIG. 3.

FIG. 6 is a schematic cross-sectional side view of an integrated device package 4 according to an embodiment. The integrated device package 4 can be generally similar to the integrated device package 2 of FIG. 2 except that the integrated device package 4 include an additional die (e.g., an integrated device die 42) between the carrier 10 and the integrated device die 22. The integrated device die 42 can be coupled to the carrier 10 by way of a connector 46. In some other embodiments, the integrated device die 42 may be coupled to the bottom side 22a of the integrated device die 22 and electrically connect to the carrier at least partially through the integrated device die 22.

The integrated device die 42 has a bottom side 42a and an top side 42b opposite the bottom side 42a. The integrated device die 42 can be positioned in the cavity 28 such that there are a gap between the bottom side 22a of the integrated device die 22 and the top side 42b of the integrated device die 42, and a gap between carrier 10 and the bottom side 42a of the integrated device die 42. In some embodiments, the bottom side 22a of the integrated device die 22 can include a sensitive portion or a moving part that is exposed to the cavity 28. For example, the integrated device die 22 can be a filter (e.g., a surface acoustic wave (SAW) filter and a bulk acoustic wave (BAW) filter).

A height of the connector 26 can be selected at least in part by a height of the top side 42b of the integrated device die 42 relative to a surface of the carrier 10 that the integrated device die 42 is mounted on. As compared to a similar package that includes two pre-packaged, stacked dies with a cap structure, the integrated device package 4 can have a reduced thickness.

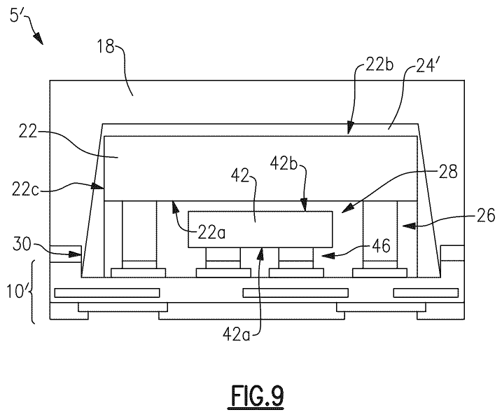

FIG. 7 is a schematic cross-sectional side view of an integrated device package 4′ according to an embodiment. The integrated device package 4′ can be generally similar to the integrated device package 4 of FIG. 6 except that a cavity seal 24′ of the integrated device package 2′ is disposed at least partially over the integrated device die 22.

FIG. 8 is a schematic cross-sectional side view of an integrated device package 5 according to an embodiment. The integrated device package 5 can be generally similar to the integrated device package 4 of FIG. 6 except that the integrated device package 5 implements the carrier 10′ in place of the carrier 10.

FIG. 9 is a schematic cross-sectional side view of an integrated device package 5′ according to an embodiment. The integrated device package 5′ can be generally similar to the integrated device package 5 of FIG. 8 except that the integrated device package 5′ implements the cavity seal 24′ in place of the cavity seal 24.

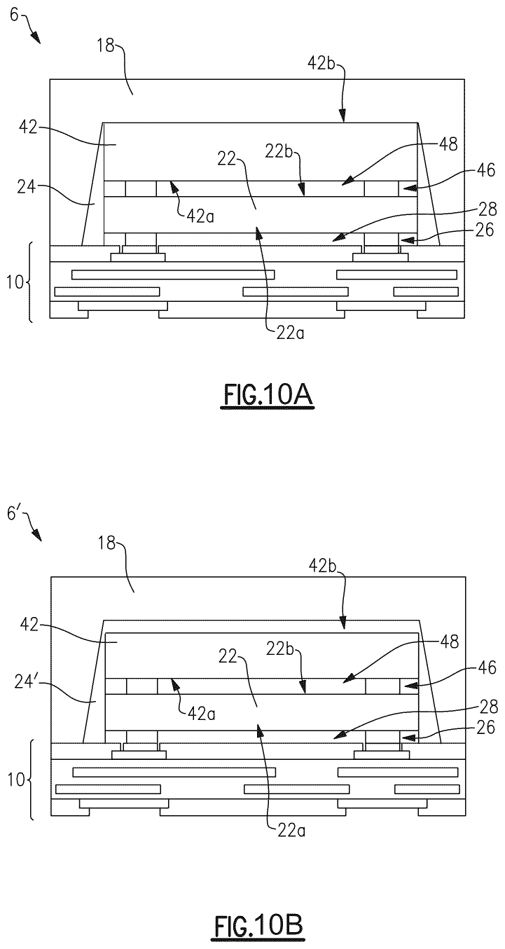

FIG. 10A is a schematic cross-sectional side view of an integrated device package 6 according to an embodiment. In the integrated device package 6, the first integrated device die 22 can be mounted to the carrier 10, and the integrated device die 42 can be mounted to the carrier 10 through the integrated device die 22. The bottom side 22a of integrated device die 22 can be spaced apart from the carrier 10 by the cavity 28 and the bottom side 42a of the integrated device die 42 can be spaced apart from the top side 22b of the integrated device die 22 by the cavity 48.

FIG. 10B is a schematic cross-sectional side view of an integrated device package 6′ according to an embodiment. The integrated device package 6′ can be generally similar to the integrated device package 6 of FIG. 10A except that the integrated device package 6′ implements the cavity seal 24′ in place of the cavity seal 24.

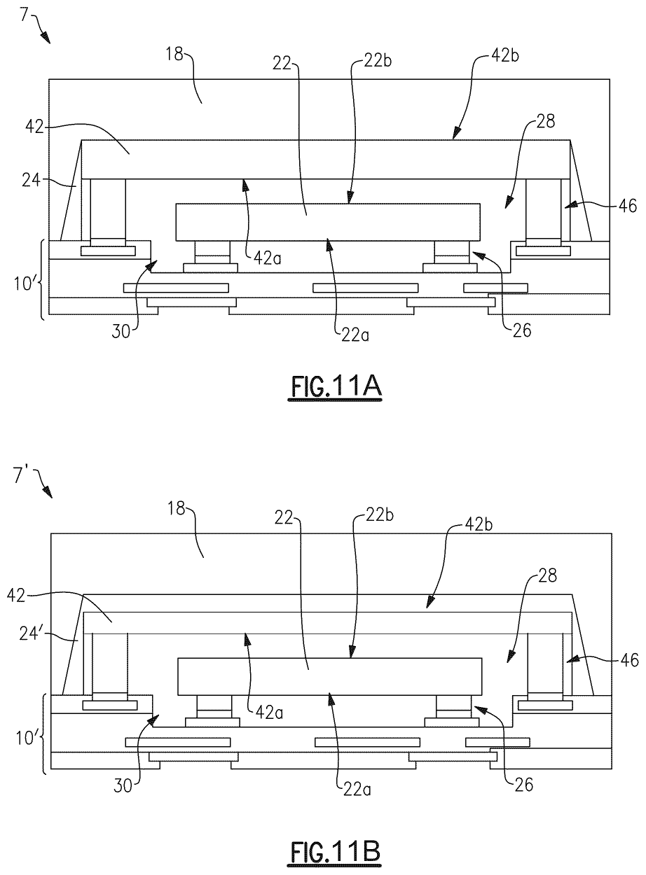

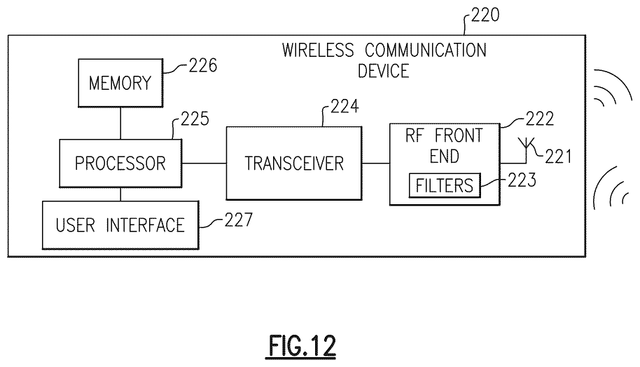

FIG. 11 is a schematic cross-sectional side view of an integrated device package 7 according to an embodiment. In the integrated device package 7, the first integrated device die 22 can be at least partially be positioned in the recess 30 of the carrier 10, and the integrated device die 42 can be positioned over the integrated device die 22.

FIG. 11B is a schematic cross-sectional side view of an integrated device package 7′ according to an embodiment. The integrated device package 7′ can be generally similar to the integrated device package 7 of FIG. 11A except that the integrated device package 7′ implements the cavity seal 24′ in place of the cavity seal 24.

In the integrated device package disclosed herein, there may be one or two dies illustrated. However, a skilled artisan will understand that there can be three or more suitable electronic components included in an integrated device package. In some embodiments, different types of electronic components can be stacked within an integrated device package.

Various embodiments of the integrated device packages disclosed herein may be implemented in any suitable electronic devices such as an acoustic wave device (e.g., mobile phone). One or more features of the integrated device packages disclosed herein can be combined or omitted in accordance with a desired specification.

FIG. 12 is a schematic diagram of a wireless communication device 220 As illustrated, the wireless communication device 220 includes an antenna 221, a radio frequency (RF) front end 222, a transceiver 224, a processor 225, a memory 226, and a user interface 227. The wireless communication device 220 can include filters 223 in the RF front end 222. The filters 223 can include one or more bulk acoustic wave (BAW) resonators. The wireless communication device 220 can be any suitable wireless communication device. For instance, a wireless communication device 220 can be a mobile phone, such as a smart phone. The antenna 221 can transmit/receive RF signals provided by the RF front end 222. Such RF signals can include carrier aggregation signals. Although not illustrated, the wireless communication device 220 can include a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An integrated device package comprising:
an integrated device die mounted to a carrier, the integrated device die having a bottom side facing the carrier and a top side opposite the bottom side;
a cavity located between the bottom side of the integrated device die and the carrier;
a cavity seal at least partially sealing the cavity; and
a molding material disposed about the integrated device die.

2. The integrated device package of claim 1 wherein the integrated device die is a surface acoustic wave filter.

3. The integrated device package of claim 1 wherein the carrier is a printed circuit board.

4. The integrated device package of claim 1 wherein the cavity is an air cavity.

5. The integrated device package of claim 1 wherein the cavity seal includes an epoxy material.

6. The integrated device package of claim 1 wherein the cavity seal and the molding material include different materials.

7. The integrated device package of claim 1 wherein the cavity is free from the molding material.

8. The integrated device package of claim 1 wherein the integrated device die is completely covered by the cavity seal.

9. The integrated device package of claim 1 wherein the carrier includes a recess, and the integrated device die is at least partially positioned in the recess.

10. The integrated device package of claim 1 further comprising an electronic component positioned between the bottom side of the integrated device die and the carrier, the electronic component electrically connected to the carrier.

11. The integrated device package of claim 1 further comprising an electronic component positioned over the top side of the integrated device die, the electronic component electrically connected to the carrier.

12. The integrated device package of claim 11 wherein the electronic component is electrically connected to the carrier through the integrated device die.

13. The integrated device package of claim 11 wherein the integrated device die is at least partially positioned in a recess formed in the carrier.

14. An integrated device package comprising:
an acoustic wave filter mounted to a carrier, the acoustic wave filter having a bottom side facing the carrier and a top side opposite the bottom side;
a cavity located between the acoustic wave filter and the carrier, the bottom side of the acoustic wave filter exposed to the cavity; and
a cavity seal at least partially sealing the cavity.

15. The integrated device package of claim 14 further comprising a molding material overmolding the acoustic wave filter.

16. The integrated device package of claim 14 wherein the carrier is a printed circuit board.

17. The integrated device package of claim 14 wherein the cavity is an air cavity.

18. The integrated device package of claim 14 wherein the cavity seal is a dielectric cavity seal.

19. A wireless communication device comprising:
an integrated device package including an integrated device die mounted to a carrier, a cavity located between the integrated device die and the carrier, and a cavity seal at least partially sealing the cavity, the integrated device package is at least partially exposed to the cavity; and
an antenna and a radio frequency front end electrically connected to the integrated device package.

20. The wireless communication device of claim 19 wherein the integrated device package is an acoustic wave filter package and the cavity seal is a dielectric cavity seal.
